(19) United States
(12) Patent Application Publication
(10) Pub. No.: US 2010/0133588 A1
(43) Pub. Date: Jun. 3, 2010

(54) SEMICONDUCTOR DEVICE HAVING DUMMY POWER LINE

(76) Inventor: Il-Woo Jung, Seoul (KR)

Correspondence Address: F. CHAU & ASSOCIATES, LLC, 130 WOODBURY ROAD, WOODBURY, NY, 11797, US

(21) Appl. No.: 12/581,548

(22) Filed: Oct. 19, 2009

(30) Foreign Application Priority Data
Dec. 3, 2008 (KR) 10-2008-0122043

(51) Int. Cl. H01L 27/105

(52) U.S. Cl. 257/204; 257/209; 257/E27.081

(57) ABSTRACT

A semiconductor device includes a plurality of circuit blocks respectively arranged both in a first direction and in a second direction that intersects the first direction. A plurality of signal lines extend in one direction of the first direction and the second direction to correspond to and extend over the circuit blocks arranged in the one direction among the plurality of circuit blocks, the signal lines being spaced apart in the other direction of the first direction and the second direction. A plurality of power lines are arranged over the circuit blocks, each power line extending along at least one of the signal lines in the one direction. A dummy power line is arranged between one of the power lines and a signal line adjacent to the one of the power lines in the other direction.

### CROSS-REFERENCE TO RELATED APPLICATION

This application claims priority to and the benefit of Korean Patent Application No. 10-2008-0122043, filed on Dec. 3, 2008, in the Korean Intellectual Property Office, the entire content of which is incorporated by reference herein.

### BACKGROUND

The present disclosures relates to semiconductor devices, and more particularly, to semiconductor memory devices and their associated power and signal lines.

Typical semiconductor memory devices have a memory cell array region and a peripheral circuit region. Signal lines for inputting and outputting data are arranged on the memory cell array region and the peripheral circuit region. As semiconductor memory devices have become more and more highly integrated and operate at high speeds, the number of signal lines have increased and power lines can become formed between various signal lines on the memory cell array region.

Since distances between the signal lines and the power lines have decreased, bridges between the signal lines and/or between the power lines can result from current draining particles being located between the signal lines and/or between the power lines. Such bridges can produce short circuits or unwanted voltage drops. Bridges so generated between the signal lines can generally be repaired. However, since a predetermined voltage signal is applied to the power lines, the bridges generated between the signal lines and the power lines cannot be repaired and can thus cause critical defects in the semiconductor memory device, thereby decreasing the manufacturing yield of the semiconductor memory devices.

### SUMMARY

Exemplary embodiments of the present invention provide a semiconductor device having a dummy power line for preventing a unwanted bridge from being generated due to a current draining particle between a signal line and a power line.

According to an exemplary embodiment of the present invention a semiconductor device includes a plurality of circuit blocks respectively arranged both in a first direction and in a second direction that intersects the first direction. A plurality of signal lines extend in one direction of the first direction and the second direction to correspond to and extend over the circuit blocks arranged in the one direction among the plurality of circuit blocks, the signal lines being spaced apart in the other direction of the first direction and the second direction. A plurality of power lines are arranged over the circuit blocks, each power line extending along at least one of the signal lines in the one direction. A dummy power line is arranged between one of the power lines and a signal line adjacent to the one of the power lines in the other direction.

The dummy power line may be floated.

Both the dummy power line and the one of the power lines may be metal lines.

The dummy power line may extend along the one of the power lines in the one direction.

The dummy power line may include a line pattern divided in the one direction, and each line pattern may be arranged to correspond to each of the circuit blocks arranged in the one direction.

The dummy power line may be electrically connected to the one of the power lines.

A connection member may electrically connect the dummy power line to the one of the power lines.

The connection member may include a fuse connected between the dummy power line and the one of the power lines.

The connection member may include both a fuse connected between the dummy power line and the one of the power lines and a MOS transistor may be connected in parallel to the fuse and have a gate to which a mode register set signal is applied.

The circuit blocks may be memory cell array.

According to an exemplary embodiment of the present invention a semiconductor power line control apparatus includes a signal line and a power line both extending substantially parallel to each other over a semiconductor circuit block. A dummy power line is between the signal line and the power line and extends over the semiconductor circuit block substantially parallel to the power line. The dummy power line is configured to be devoid of power upon a determination that a current draining particle foreign to the semiconductor circuit block is in contact with both the dummy power line and the signal line.

A fuse may be coupled between the dummy power line and the power line, the fuse being configured to open circuit upon the determination that the current draining particle is in contact with both the dummy power line and the signal line.

The semiconductor power line control apparatus may further include a MOS transistor whose source and drain are respectively connected in parallel to the fuse and whose gate is responsive to a control signal such that when a determination is made that the current draining particle is not in contact with the dummy power line and the signal line, the MOS transistor allows the dummy power line and the power line to be connected, and when a determination is made that the current draining particle is in contact with the dummy power line and the signal line, the MOS transistor does not allow the dummy power line and the power line to be connected.

The semiconductor circuit block may be a memory cell array.

The semiconductor circuit block may be adjacent a second semiconductor circuit block in a direction substantially parallel to the power line and the power line, the signal line and the dummy power line may each extend both from over the semiconductor circuit block to over the second semiconductor circuit block.

The semiconductor circuit block may be adjacent a second semiconductor circuit block in a direction substantially parallel to the power line and the power line and signal line may each extend from over the semiconductor circuit block to over the second semiconductor circuit block while the dummy power line does not extend from over the semiconductor circuit block to over the second semiconductor circuit block.

The semiconductor power line control apparatus may further include a second signal line substantially parallel to the signal line, the power line being between the signal line and the second signal line, and a second dummy power line between the power line and the second signal line.

A second fuse may be coupled between the second dummy power line and the power line, the second fuse being configured to open circuit upon the determination that a second foreign current draining particle is in contact with both the second dummy power line and the second signal line.

The semiconductor power line control apparatus may further include a second MOS transistor whose source and drain are respectively connected in parallel to the second fuse and whose gate is responsive to the control signal such that when a determination is made that the second current draining particle is not in contact with the second dummy power line and the second signal line, the second MOS transistor allows the second dummy power line and the power line to be connected, and when a determination is made that the second current draining particle is in contact with the second dummy power line and the second signal line, the second MOS transistor does not allow the second dummy power line and the power line to be connected.

According to an exemplary embodiment of the present invention a memory cell array power line control apparatus includes a signal line and a power line both extending substantially parallel to each other over at least a pair of adjacent memory cell arrays and a dummy power line between the signal line and the power line and extending over at least a pair of adjacent memory cell arrays substantially parallel to the power line. The dummy power line is configured to be devoid of power upon a determination that a current draining particle foreign to one of the pair of adjacent memory cell arrays is in contact with both the dummy power line and the signal line.

### BRIEF DESCRIPTION OF THE DRAWINGS

Exemplary embodiments of the present invention will now be described in the following detailed description taken in conjunction with the accompanying drawings in which:

FIG. 1 is a block diagram illustrating the structure of a semiconductor device according to an exemplary embodiment of the present invention;

FIG. 2A is a schematic plan view illustrating an arrangement of power lines, signal lines, and dummy power lines of the semiconductor device of FIG. 1 according to an exemplary embodiment of the present invention;

FIG. 2B is a schematic plan view illustrating an exemplary embodiment the arrangement of power lines, signal lines, and dummy power lines of the semiconductor device of FIG. 1 according to an exemplary embodiment of the present invention;

FIG. 3A is a schematic plan view illustrating a connection between the power lines and the dummy power lines of the semiconductor device of FIG. 2A or 2B according to an exemplary embodiment of the present invention;

FIG. 3B is a schematic plan view illustrating a connection between the power lines and the dummy power lines of the semiconductor device of FIG. 2A or 2B according to an exemplary embodiment of the present invention;

FIGS. 4A, 4B and 4C are schematic plan views for explaining the probability that a bridge will be generated due to a current draining particle in a semiconductor device where a dummy power line is not formed between a power line and a signal line; and

FIG. 5 is a schematic plan view for explaining the probability that a bridge will be generated due to a current draining particle in a semiconductor device where a dummy power line is formed between a power line and a signal line.

### DETAILED DESCRIPTION OF THE EXEMPLARY EMBODIMENTS

Exemplary embodiments of the present invention will now be described more fully with reference to the accompanying drawings. The exemplary embodiments may, however, be embodied in many different forms and should not be construed as being limited to the embodiments set forth herein. In the drawings, the thicknesses of layers and regions may be exaggerated for clarity. Like reference numerals in the drawings denote like elements.

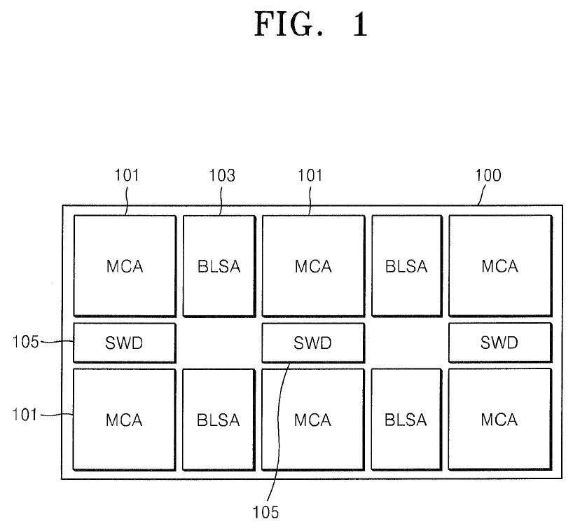

FIG. 1 is a view illustrating the structure of a semiconductor device 100 according to an exemplary embodiment of the present invention. The semiconductor device 100 includes a plurality of memory cell arrays 101 arranged in both a first (e.g., row) direction and a second (e.g., column) direction that intersects the first direction. In the memory cell arrays 101, a plurality of memory cells (not shown) are respectively arranged both in the first direction and in the second direction.

Sense amplifiers 103 for sensing a bit line (not shown) connected to the memory cells are respectively arranged at side portions of the memory cell arrays 101 in the first direction. Sub-word line drivers 105 for driving word lines (not shown) connected to the memory cells are respectively arranged at the other side portions of the memory cell arrays 101 in the second direction. The semiconductor device 10 further includes control circuits (not shown) for controlling the sense amplifiers 103 and the sub-word line drivers 105.

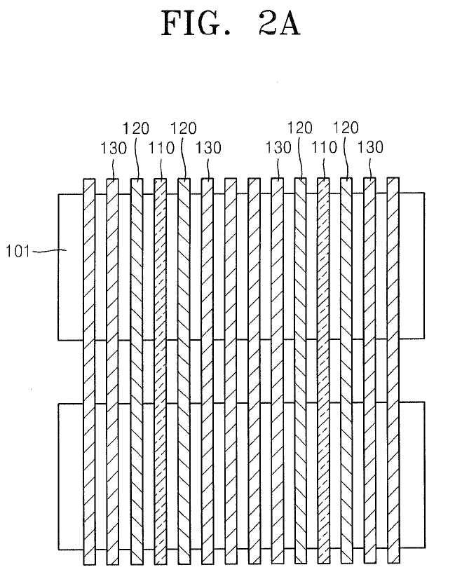

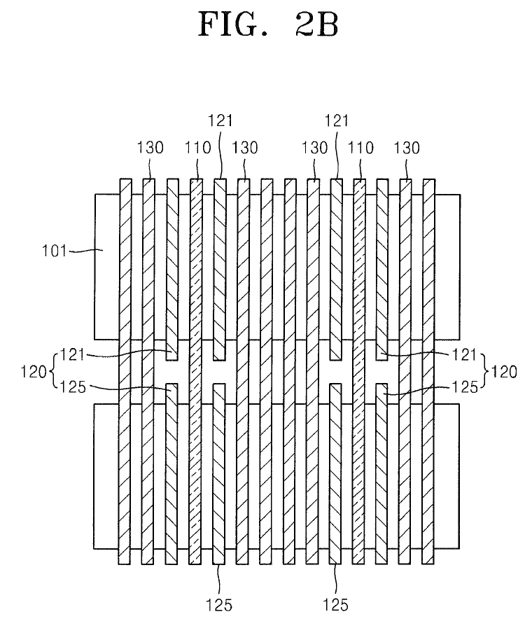

FIG. 2A is a schematic plan view illustrating an arrangement of power lines 110, signal lines 130, and dummy power lines 120 of the semiconductor device 100 of FIG. 1, according to an exemplary embodiment of the present invention. FIG. 2B is a schematic plan view illustrating an arrangement of the power lines 110, the signal lines 130, and the dummy power lines 120′ of the semiconductor device 100 of FIG. 1. FIGS. 2A and 2B illustrate only two adjacent pairs of the memory cell arrays 101 in the second direction of semiconductor device 101, but without showing the sub-word line driver 105 therebetween.

Referring to FIGS. 2A and 2B, the signal lines 130 are arranged in the second (column) direction on the memory cell arrays 101 which are arranged both in the first (row) and in the second (column) direction from among the plurality of memory cell arrays 101. The signal lines 130 are arranged such that the signal lines 130 are spaced apart from one another in the memory cell arrays 101 in the first direction. The signal lines 130 include signal lines for providing a word line enable signal (NWE) which is received from a sub-word line driver 105 (as shown in FIG. 1, but not shown in FIGS. 2A and 2B) to the memory cells arranged in the memory cell array 101.

At least one power line 110 is formed between the signal lines 130 in the memory cell array 101 in the second direction. The power lines 110 are arranged substantially parallel to the signal lines 130 in the second direction, and include a power line for providing a high power voltage (VP), a low power voltage (VSSA), or an internal voltage (VINTA) that are applied to a memory cell, etc. The power lines 110 can be metal lines.

As seen in FIG. 2A, at least one dummy power line 120 is formed between the power line 110 that is formed in the memory cell array 101 and a signal line 130 that is adjacent to the power line 110 in the second direction. The dummy power lines 120 are arranged to extend along the power lines 110 in the second direction. The dummy power lines 120 are floated and include the same material as the power lines 110. The dummy power lines 120 can also be metal lines.

Alternatively, as seen in FIG. 2B, the dummy power lines 120′ can include divided line patterns 121, 125, and the divided line patterns 121, 125 are arranged to correspond to each of the memory cell arrays 101 without connecting to a dummy power line in its adjacent memory cell array. The dummy power lines 120′ are floated and include the same material as the power lines 110. The dummy power lines 120′ can also be metal lines.

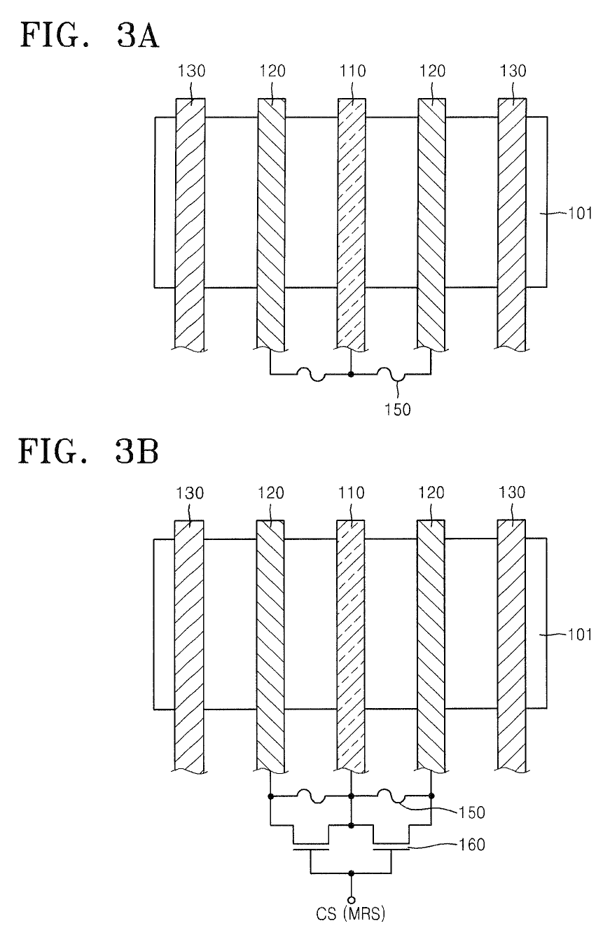

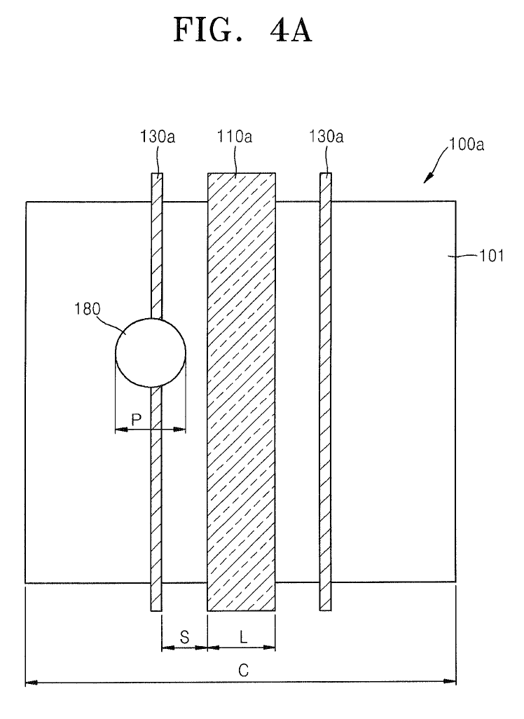

FIG. 3A is a schematic plan view illustrating a connection between power lines 110 and dummy power lines 120 of FIG. 2A according to an exemplary embodiment of the present invention. Similar connections (not shown) can be applied between the power lines 110 and the dummy power lines 120′ of FIG. 2B. FIG. 3B is another schematic plan view illustrating a connection between the power lines 110 and the dummy power lines 120, 120′ of FIGS. 2A and 2B according to an exemplary embodiment of the present invention. FIGS. 3A and 3B illustrate only one of the memory cell arrays 101.

Referring to FIGS. 3A and 3B, the power line 110 and at least one of the dummy power lines 120 formed at both side portions of the power lines 110 are connected to each other through a connection member, and the dummy power line 120 can be used as a power line. The connection member includes a plurality of fuses 150 connected between the power lines 110 and the dummy power lines 120, and can include a polyfuse or an electrical-fuse (E-fuse).

After testing is performed, and when a undesirable bridge is determined to have been generated as a result of a current draining particle being between the signal line 130 and the dummy power line 120, each of the fuses 150 can be corresponding cut off to separate the dummy power line 120 having an intruding bridge from the power line 110. Accordingly, the dummy power lines 120 would be floated without being used as a power line.

Otherwise, when a bridge is not generated due to a particle between the signal line 130 and the dummy power line 120, the dummy power lines 120 and the power lines 110 can be electrically connected to each other without cutting off the fuses 150. Accordingly, the dummy power lines 120 can be used as a further power line to decrease noise.

In FIG. 3B the connection member includes the fuses 150, which are connected between the power lines 110 and the dummy power lines 120, and switching devices 160 connected substantially in parallel to the fuses 150. The switching devices 160 may include MOS transistors (hereinafter, switching device 160 are referred to as MOS transistor(s) 160). A signal CS is applied to a gate of the MOS transistors 160 to test the generation of a bridge between the signal line 130 and the dummy power line 120 during the testing. The signal CS may include a mode register set signal (MRS).

After the testing is performed, when a bridge is generated and thus the fuses 150 are cut off, the signal CS is blocked at the gate of the MOS transistor 160 to separate the dummy power lines 120 from the power lines 110. Accordingly, the dummy power lines 120 are floated without being used as a power line. Otherwise, when a bridge is not generated, the dummy power lines 120 and the power lines 110 are electrically connected to each other through the MOS transistors 160.

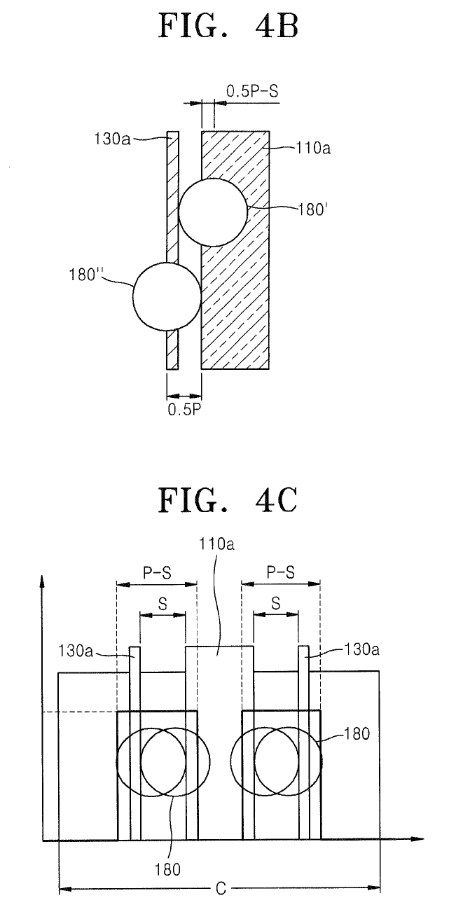

FIGS. 4A through 4C are schematic plan views for explaining how a bridge can be generated resulting from a current draining particle in a semiconductor device 100a when a dummy power line 120 is not formed between a power line 110a and a signal line 130a.

Referring to FIG. 4A, in a memory cell array 101, only a bridge that is generated due to a particle 180 between the power line 110a and the signal lines 130a is calculated. It is assumed that the size of the memory cell array 101 in the first direction is “c”, the width of the power line 110a in the memory cell array 101 is “L” which is uniform, and an interval between the signal line 130a and the power line 110a is “S”. Also, it is assumed that the diameter of the particle 180 in a width direction (the first direction) of the power line 110a and the signal lines 130a is “P”, and the size P of the particle 180 is smaller than the size obtained by combining together the width L of the power line 110a and the widths of the signal lines 130a, 130b.

Referring to FIG. 4B, example cases where a bridge is generated between the power line 110a and the signal line 130a arranged at one side of the power line 110a can include the bridge happening: (1) when a particle 180′ is formed over the power line 110a and contacts an edge portion of signal line 130a facing the power line 110a and (2) when a particle 180″ is formed over the signal line 130a and contacts an edge portion of the power line 110a.

Referring to FIG. 4C, the probability that a bridge is generated due to a particle 180 between a power line 110a and a signal line 130a, which is arranged at one side of the power line 110a, is (P−S), and the probability that a bridge is generated due to the particle 180 between the power line 110a and the signal line 130a, which is arranged at the other side of the power line 110a, is also (P−S).

Accordingly, the probability that a bridge is generated between the power line 110a and the signal line 130a, which are arranged at both sides of the power line 110a, is 2(P−S). The probability that a bridge is generated due to the particle 180 between the power line 110a and the signal line 130a in the memory cell array 101 having the size of C in the first direction is 2(P−S)/C.

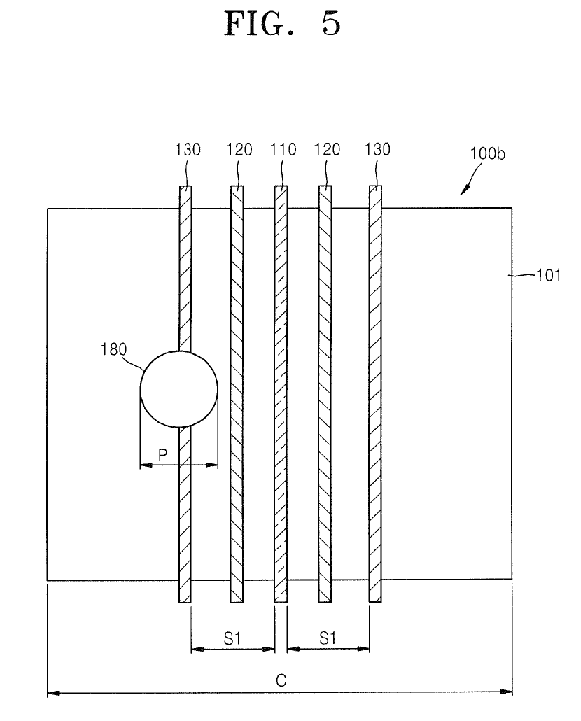

FIG. 5 is a schematic plan view for explaining how a bridge generation due to a current draining particle in a semiconductor device 100 can be minimized when a dummy power line 120 is arranged between a power line 110 and a signal line 130. The probability of the generation of a bridge is calculated under the same conditions as the semiconductor device 100a of FIGS. 4A through 4C.

Referring to FIG. 5, in the semiconductor device 100, the dummy power lines 120 are arranged at both sides of the power line 110 by dividing the power line 110a depicted in FIG. 4A into three equal parts. In the semiconductor device 100b, the probability that a bridge is generated due to a particle 180 between the power line 110 and the signal line 130 is 2(P−S1)/C. An interval S1 between the power line 110 and the signal line 130 is increased by the widths of the dummy power lines 120 arranged between the power line 110 and the respective signal lines 130.

Accordingly, the probability that a bridge is generated in the semiconductor device 100b is 2(P−S1)/C, similar to the semiconductor device 100a of FIGS. 4A through 4C. However, the interval S1 between the power line 110 and the signal line 130 in the semiconductor device 100 is greater than an interval S in the semiconductor device 100a of FIGS. 4A through 4C. Therefore, when the dummy power line 120 is disposed between the power line 110 and the signal line 130, the probability of the generation of a bridge decreases.

Table 1 below shows the probability that a bridge will be generated in the semiconductor devices 100a and 100b. Referring to Table 1, columns I and II show the possibilities of generation of a bridge when thirty-two power lines and twelve power lines are respectively arranged in one memory cell array, in the semiconductor device 100a where a dummy power line is not disposed between a power line and a signal line. Column III shows the probability of the generation of a bridge when thirty-two power lines are arranged in one memory cell array, in the semiconductor device 100b where a dummy power line is disposed between a power line and a signal line.

TABLE 1

| | | I (32) | II (12) | III (32) |
|---|---|---|---|---|
| Size of | 0.25 | 4.2% | 1.7% | 0.0% |
| particle | 0.3 | 9.4% | 3.8% | 0.0% |
| (um) | 0.35 | 14.6% | 5.9% | 0.0% |
| | 0.4 | 19.9% | 8.1% | 0.0% |
| | 0.45 | 25.1% | 10.2% | 3.1% |
| | 0.5 | 30.3% | 12.3% | 8.4% |

Referring to Table 1, the more power lines that are arranged in one memory cell array, the greater the probability that a bridge will be generated due to a current draining particle between the power line and the signal line. Also, as the size of the current draining particle increases, the probability of generation of a bridge increases. The probability that a bridge is generated is significantly decreased due to the dummy power lines when the dummy power line is disposed between the power line and the signal line, as compared to when the dummy power line is not disposed therebetween.

While the present invention has been particularly shown and described with reference to exemplary embodiments thereof, it will be understood that various changes in form and in details may be made therein without departing from the spirit, and scope of the following claims.

What is claimed is:

1. A semiconductor device comprising:
a plurality of circuit blocks respectively arranged both in a first direction and in a second direction that intersects the first direction;
a plurality of signal lines extending in one direction of the first direction and the second direction to correspond to and extend over the circuit blocks arranged in the one direction among the plurality of circuit blocks, the signal lines spaced apart in the other direction of the first direction and the second direction;
a plurality of power lines arranged over the circuit blocks, each power line extending along at least one of the signal lines in the one direction; and
a dummy power line arranged between one of the power lines and a signal line adjacent to the one of the power lines in the other direction.

2. The semiconductor device of claim 1, wherein the dummy power line is floated.

3. The semiconductor device of claim 1, wherein both the dummy power line and the one of the power lines comprise metal lines.

4. The semiconductor device of claim 1, wherein the dummy power line extends along the one of the power lines in the one direction.

5. The semiconductor device of claim 1, wherein the dummy power line comprises a line pattern divided in the one direction, and each line pattern is arranged to correspond to each of the circuit blocks arranged in the one direction.

6. The semiconductor device of claim 1, wherein the dummy power line is electrically connected to the one of the power lines.

7. The semiconductor device of claim 6, further comprising a connection member that electrically connects the dummy power line to the one of the power lines.

8. The semiconductor device of claim 7, wherein the connection member comprises a fuse connected between the dummy power line and the one of the power lines.

9. The semiconductor device of claim 7, wherein the connection member comprises:
a fuse connected between the dummy power line and the one of the power lines; and
a MOS transistor connected in parallel to the fuse and having a gate to which a mode register set signal is applied.

10. The semiconductor device of claim 1, wherein the circuit blocks comprise memory cell arrays.

11. A semiconductor power line control apparatus comprising:
a signal line and a power line both extending substantially parallel to each other over a semiconductor circuit block; and
a dummy power line between the signal line and the power line and extending over the semiconductor circuit block substantially parallel to the power line,
wherein the dummy power line is configured to be devoid of power upon a determination that a current draining particle foreign to the semiconductor circuit block is in contact with both the dummy power line and the signal line.

12. The semiconductor power line control apparatus of claim 11, wherein a fuse is coupled between the dummy power line and the power line, the fuse being configured to open circuit upon the determination that the current draining particle is in contact with both the dummy power line and the signal line.

13. The semiconductor power line control apparatus of claim 11, further comprising a MOS transistor whose source and drain are respectively connected in parallel to the fuse and whose gate is responsive to a control signal such that:
when a determination is made that the current draining particle is not in contact with the dummy power line and the signal line, the MOS transistor allows the dummy power line and the power line to be connected, and
when a determination is made that the current draining particle is in contact with the dummy power line and the signal line, the MOS transistor does not allow the dummy power line and the power line to be connected.

14. The semiconductor power line control apparatus of claim 11, wherein the semiconductor circuit block is a memory cell array.

15. The semiconductor power line control apparatus of claim 11,
wherein the semiconductor circuit block is adjacent a second semiconductor circuit block in a direction substantially parallel to the power line; and
wherein the power line, the signal line and the dummy power line, each extend both from over the semiconductor circuit block to over the second semiconductor circuit block.

16. The semiconductor power line control apparatus of claim 11,
wherein the semiconductor circuit block is adjacent a second semiconductor circuit block in a direction substantially parallel to the power line; and
wherein the power line and signal line each extend from over the semiconductor circuit block to over the second semiconductor circuit block while the dummy power line does not extend from over the semiconductor circuit block to over the second semiconductor circuit block.

17. The semiconductor power line control apparatus of claim 11, further comprising:
a second signal line substantially parallel to the signal line, the power line being between the signal line and the second signal line; and
a second dummy power line between the power line and the second signal line.

18. The semiconductor power line control apparatus of claim 17, wherein a second fuse is coupled between the second dummy power line and the power line, the second fuse being configured to open circuit upon the determination that a second current draining foreign particle is in contact with both the second dummy power line and the second signal line.

19. The semiconductor power line control apparatus of claim 18, further comprising a second MOS transistor whose source and drain are respectively connected in parallel to the second fuse and whose gate is responsive to the control signal such that:
when a determination is made that the second current draining particle is not in contact with the second dummy power line and the second signal line, the second. MOS transistor allows the second dummy power line and the power line to be connected, and
when a determination is made that the second current draining particle is in contact with the second dummy power line and the second signal line, the second MOS transistor does not allow the second dummy power line and the power line to be connected.

20. A memory cell array power line control apparatus comprising:
a signal line and a power line both extending substantially parallel to each other over at least a pair of adjacent memory cell arrays; and
a dummy power line between the signal line and the power line and extending over at least a pair of adjacent memory cell arrays substantially parallel to the power line,
wherein the dummy power line is configured to be devoid of power upon a determination that a current draining particle foreign to one of the pair of adjacent memory cell arrays is in contact with both the dummy power line and the signal line.
